(19) United States
(12) Patent Application Publication
(10) Pub. No.: US 2009/0209110 A1
(43) Pub. Date: Aug. 20, 2009

(54) SPIN ETCHING METHOD FOR SEMICONDUCTOR WAFER

(75) Inventors: Ayumu Okano, Ota-Ku (JP); Osamu Nagai, Ota-ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/363,551

(22) Filed: Jan. 30, 2009

(30) Foreign Application Priority Data
Feb. 14, 2008 (JP) 2008-032733

(51) Int. Cl. H01L 21/465

(52) U.S. Cl. 438/748; 257/E21.485

(57) ABSTRACT

A spin etching method for etching a back-side surface of a semiconductor wafer provided with a plurality of devices on the face side and subjected to back grinding, wherein the semiconductor wafer is held with its back-side surface down, and the back-side surface of the semiconductor wafer is supplied with an etching liquid from an etching liquid supply nozzle disposed on the lower side of the semiconductor wafer while the semiconductor wafer being rotated.

### BACKGROUND OF THE INVENTION

1. Field of the Invention

The present invention relates to a spin etching method for semiconductor wafer, for chemically etching a ground surface of a semiconductor wafer after the semiconductor wafer is subjected to back grinding.

2. Description of the Related Art

A semiconductor wafer which is provided with a multiplicity of devices such as ICs and LSIs on the face side and in which the regions of the individual devices are demarcated by planned dividing lines (streets) is thinned to a predetermined thickness by back grinding conducted by use of a grinding apparatus. Then, the semiconductor wafer is cut along the planned dividing lines by a dicing apparatus into the individual devices, which are used in electric apparatuses such as mobile phones and personal computers. The back grind of the semiconductor wafer is generally carried out by a grinding apparatus including grinding means, in which a grinding wheel having a grinding stone or stones is rotataby supported, and a chuck table which is disposed to face the grinding means and which holds the semiconductor wafer. By the grinding apparatus, the semiconductor wafer can be processed (thinned) to the predetermined thickness.

Since the grinding of the semiconductor wafer is accomplished through microscopic brittle fracture by the grinding stone or stones, a plurality of microscopic strains are generated in the ground surface, leading to a lowering in the die strength of the semiconductor chips (devices). To cope with this problem, therefore, the back-side surface (ground surface) of the semiconductor wafer after the grinding is etched with an etching liquid by, for example, a depth of a few micrometers, so as to remove the strains produced by the grinding. This etching step is generally carried out by a spin etching method in which an etching liquid is dropped onto the semiconductor wafer while the semiconductor wafer is kept spinning (refer to, for example, Japanese Patent Laid-open No. Hei 7-20180).

On the other hand, the electronic apparatuses in recent years have been tending to be reduced in weight and size, and the back-side surfaces of the semiconductor wafers are ground by a grinding apparatus to obtain a wafer thickness of about 50 μm or below. The semiconductor wafer ground to be thin in this manner is difficult to handle, and may be broken during transportation or the like. In view of this, there has been proposed a technology in which only that region of the back-side surface of a semiconductor wafer which corresponds to the device region is ground, to leave an annular reinforcement part in that region of the back-side surface of the semiconductor wafer which corresponds to the peripheral marginal region surrounding the device region (refer to, for example, Japanese Patent Laid-open No. 2007-19461).

In the case where the semiconductor wafer thus provided with a recessed part in the back-side surface (the surface to be etched, which will hereinafter be referred to as “the etching surface”) thereof is subjected to spin etching, the etching liquid would stagnate in the recessed part, making it difficult to etch the whole back-side surface of the wafer uniformly. Besides, the etching liquid would be concentrated in the direction toward the circumference of the semiconductor wafer due to the centrifugal force, and the annular reinforcement part would be etched excessively, rendering the wafer fragile.

### SUMMARY OF THE INVENTION

Accordingly, it is an object of the present invention to provide a spin etching method for semiconductor wafer by which even a semiconductor wafer provided with a recessed part in the etching surface can be etched uniformly, while avoiding excessive etching of the annular reinforcement part.

In accordance with an aspect of the present invention, there is provided a spin etching method for semiconductor wafer, for etching a back-side surface of a semiconductor wafer provided with a plurality of devices on the face side thereof and subjected to back grinding, the spin etching method including the steps of: holding the semiconductor wafer, with the back-side surface directed downward; and supplying the back-side surface of the semiconductor wafer with an etching liquid from an etching liquid supply nozzle disposed on the lower side of the semiconductor wafer while rotating the semiconductor wafer.

Preferably, the etching liquid supply nozzle has a plate-like shape part provided with one or a plurality of etching liquid jet ports. Preferably, the semiconductor wafer as an object of etching has a device region in which the plurality of devices are formed on the face side, and a peripheral marginal region surrounding the device region, and that region of the back-side surface (the etching surface) of the semiconductor wafer which corresponds to the device region is preliminarily ground before etching so that an annular projected part (reinforcement part) is formed in that region of the back-side surface of the semiconductor wafer which corresponds to the peripheral marginal region.

According to the present invention, the semiconductor wafer is supplied with the etching liquid from the etching liquid supply nozzle arranged on the lower side of the etching surface of the semiconductor wafer. This ensures that, even in the case of a semiconductor wafer provided with a recessed part in the etching surface thereof, stagnation of the etching liquid in the recessed part is obviated, so that the etching surface as a whole can be etched uniformly, and excessive etching of the annular reinforcement part can be prevented from occurring.

In addition, the etching is conducted while the etching surface is directed downwards. This ensures that, even in the case of a semiconductor wafer not provided with any recessed part in the etching surface thereof, infiltration of the etching liquid into non-etching surfaces of the semiconductor wafer can be obviated.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a face-side perspective view of a semiconductor wafer;

FIG. 2 is a back-side perspective view of the semiconductor wafer;

FIG. 3 is a back-side perspective view of a semiconductor wafer having a ground recessed part and an annular reinforcement part;

FIG. 4 is a partly sectional illustration of a spin etching method using an etching liquid supply nozzle according to a first embodiment of the present invention;

FIG. 5 is a partly sectional illustration of a spin etching method using an etching liquid supply nozzle according to a second embodiment of the present invention; and

FIG. 6 is a partly sectional illustration of a spin etching method using an etching liquid supply nozzle according to a third embodiment of the present invention.

### DETAILED DESCRIPTION OF THE PREFERRED EMBODIMENTS

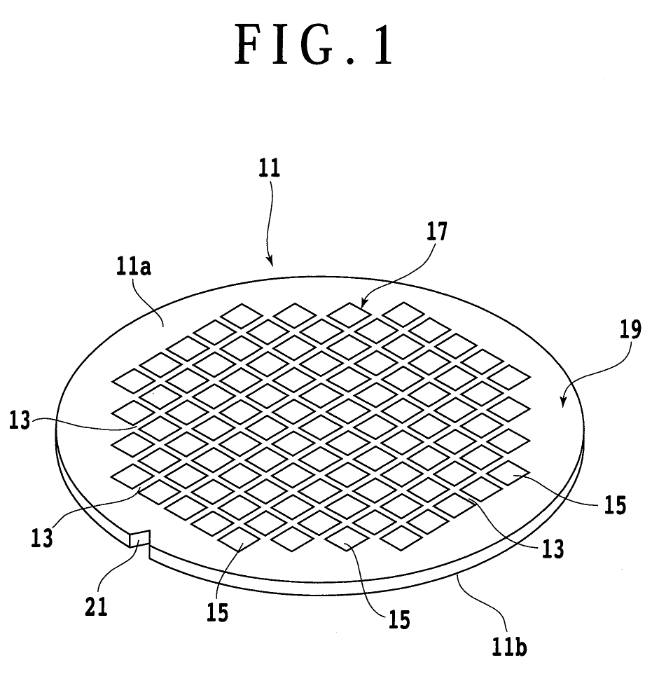

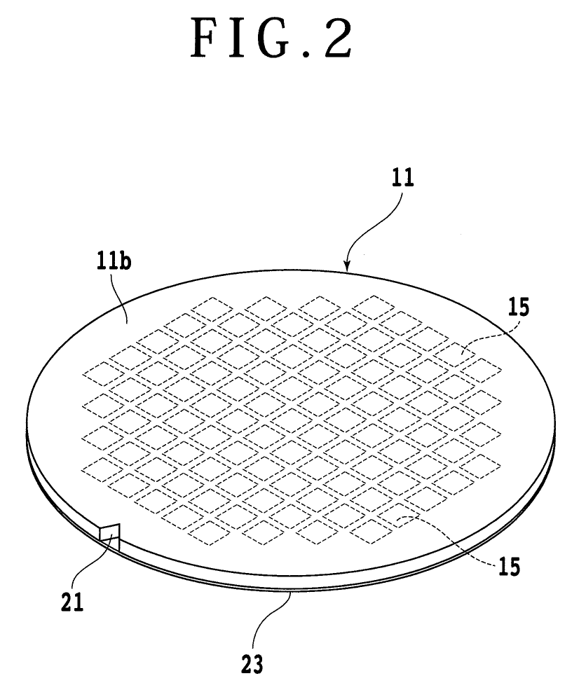

Now, the spin etching method for semiconductor wafer according to the present invention will be described in detail below, referring to the drawings. FIG. 1 is a perspective view of a semiconductor wafer before processed (thinned) to a predetermined thickness. FIG. 2 is a back-side perspective view of the semiconductor wafer. The semiconductor wafer 11 shown in FIG. 1 is composed, for example, of a silicon wafer having a thickness of 600 μm, a face-side surface 11a of which is provided with a plurality of streets 13 in a grid pattern, and devices 15 such as ICs and LSIs are formed in a plurality of regions demarcated by the plurality of streets 13.

The semiconductor wafer 11 configured as above has a device region 17 in which the devices 15 are formed, and a peripheral marginal region 19 surrounding the device region 17. In addition, the semiconductor wafer 11 is provided in its circumference with a notch 21 as a mark which indicates the crystal orientation of the silicon wafer. To the face-side surface 11a of the semiconductor wafer 11, a protective tape 23 is adhered in a protective tape adhering step. Therefore, the face-side surface 11a of the semiconductor wafer 11 is protected by the protective tape 23, whereas the back-side surface 11b is exposed, as shown in FIG. 2.

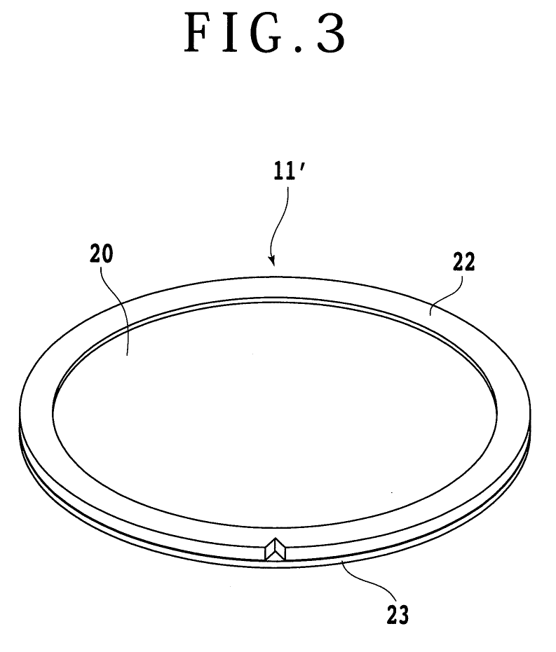

Referring to FIG. 3, there is shown a back-side perspective view of a semiconductor wafer 11′, wherein only that region of the back-side surface of the semiconductor wafer which corresponds to the device region 17 is ground, to form a recessed part 20, and that region of the back-side surface which corresponds to the peripheral marginal region 19 is left as an annular reinforcement part 22. The thickness of the recessed part 20 is, for example, about 50 μm. Since the grinding of the semiconductor wafer is accomplished through microscopic brittle fracture by a grinding stone or stones, a plurality of microscopic strains are generated in the ground surface, leading to a lowering in the die strength or transverse rapture strength of the semiconductor chips (devices). To cope with this problem, the ground surface of the semiconductor wafer is etched with an etching liquid, so as to remove the strains produced by the grinding.

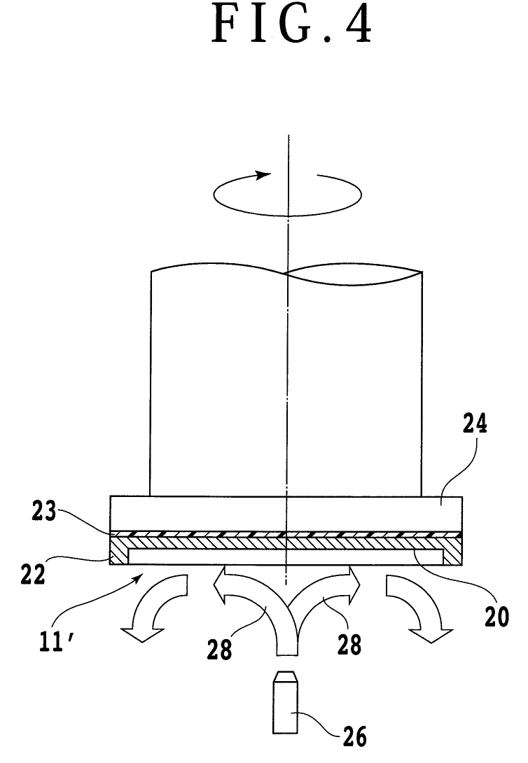

Now, referring to FIGS. 4 to 6, the spin etching method according to an embodiment of the present invention will be described in detail below. First, referring to FIG. 4, symbol 24 denotes a wafer holding table, and the semiconductor wafer 11′ having the recessed part 20 and the annular reinforcement part 22 is held by the wafer holding table 24, with its back-side surface (etching surface) directed down. While rotating the wafer holding table 24 at, for example, 1000 rpm, an etching liquid is jetted from an etching liquid supply nozzle 26 according to the first embodiment, which is arranged on the lower side of the wafer 11′, to be supplied to the etching surface (recessed part) 20 of the semiconductor wafer 11′ as indicated by arrows 28. Where the semiconductor wafer 11′ is made of silicon, the etching liquid may be a liquid mixture of hydrofluoric acid and nitric acid. The pressure at which the etching liquid is jetted from the etching liquid supply nozzle 26 is suitably about 0.8 kg/cm².

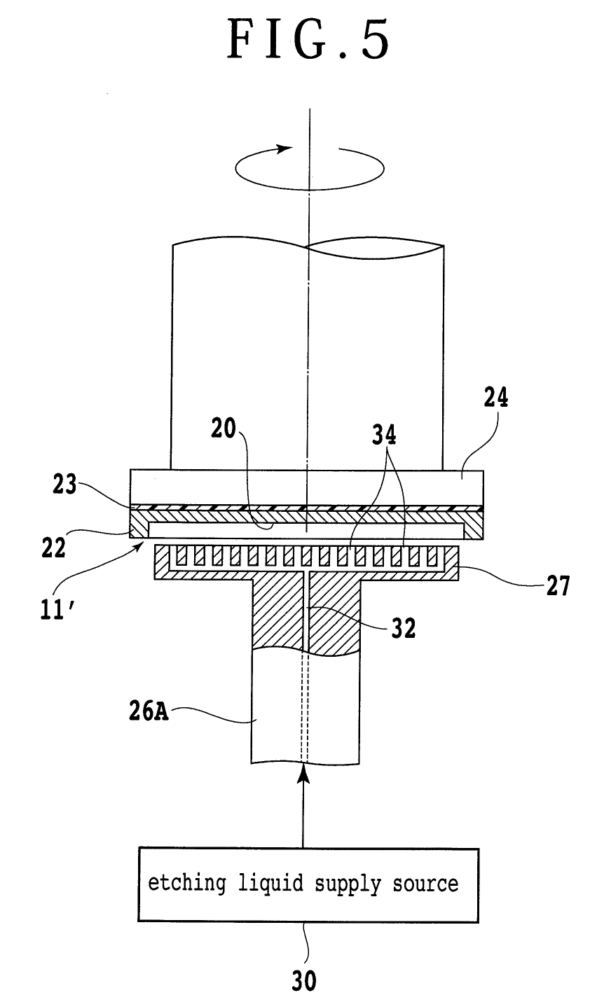

Referring to FIG. 5, there is shown a sectional view of an etching liquid supply nozzle 26A according to a second embodiment of the present invention. The etching liquid supply nozzle 26A has a circular disk-shaped part 27 at a tip part thereof, and the circular disk-shaped part 27 is provided with a plurality of etching liquid jet ports 34 communicating with an etching liquid supply passage 32. The etching liquid jet ports 34 may be formed in multiplicity over the whole area of the circular disk-shaped part 27, or may be formed as annular etching liquid jet ports.

Where the semiconductor wafer 11′ is a silicon wafer, an etching liquid supply source 30 supplies an etching liquid composed of a liquid mixture of hydrofluoric acid and nitric acid. The wafer holding table 24 is rotated at 1000 rpm, for example. According to the present embodiment, the circular disk-shaped part 27 is provided with the multiplicity of etching liquid jet ports 34, so that the recessed part 20 of the wafer 11′ can be etched uniformly.

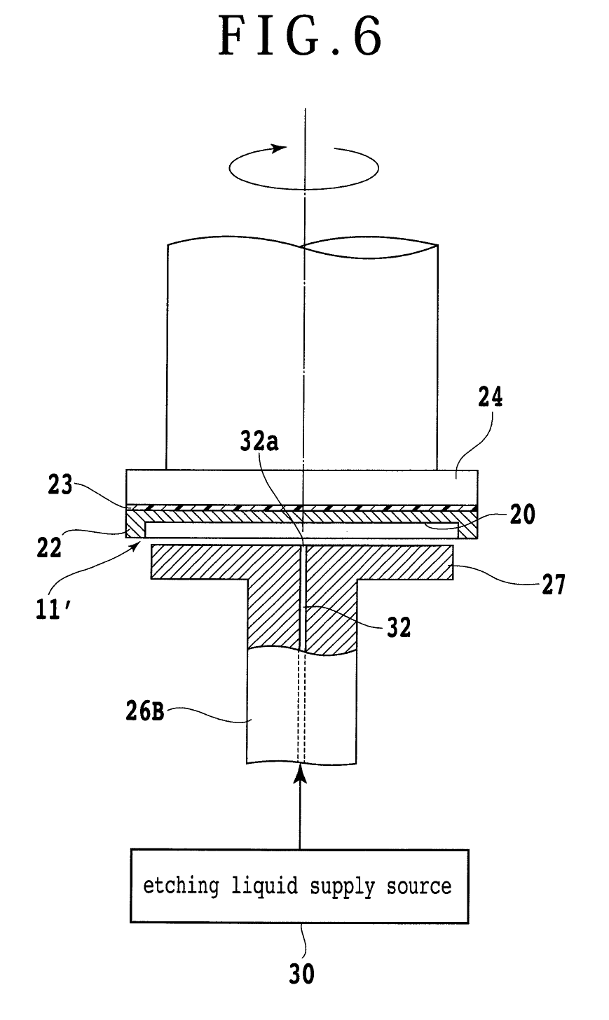

Referring to FIG. 6, there is shown a spin etching method using an etching liquid supply nozzle 26B according to a third embodiment of the present invention. The etching liquid supply nozzle 26B has a circular disk-shaped part 27, which is provided in its central portion with a single etching liquid jet port 32a communicating with an etching liquid supply passage 32. In the case where such an etching liquid supply nozzle 26B is used, also, the ground recessed part 20 of the wafer 11′ can be etched, thereby removing the strains arising from grinding.

According to the embodiments described above, the semiconductor wafer is held by the wafer holding table, with its etching surface directed down, and the etching liquid is supplied to the semiconductor wafer from the etching liquid supply nozzle while rotating the wafer by the holding table. This ensures that, even in the case of a semiconductor wafer having a recessed part 20 in the etching surface thereof, the etching liquid would not stagnate in the recessed part 20, so that the etching surface as a whole can be etched uniformly, and excessive etching of the annular reinforcement part 22 can be prevented from occurring.

The spin etching method according to the present invention is not limited to the above-described embodiments. Even in the case of etching an ordinary semiconductor wafer not having any recessed part in its etching surface, the supply of the etching liquid from the lower side according to the invention makes it possible to prevent infiltration of the etching liquid into non-etching surfaces of the wafer.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A spin etching method for semiconductor wafer, for etching a back-side surface of a semiconductor wafer provided with a plurality of devices on a face side and subjected to back grinding, said spin etching method comprising the steps of:
holding said semiconductor wafer, with said back-side surface directed downward; and
supplying said back-side surface of said semiconductor wafer with an etching liquid from an etching liquid supply nozzle disposed on the lower side of said semiconductor wafer while rotating said semiconductor wafer.

2. The spin etching method for semiconductor wafer as set forth in claim 1, wherein said etching liquid supply nozzle has a plate-like shape part provided with one or a plurality of etching liquid jet ports.

3. The spin etching method for semiconductor wafer as set forth in claim 1, wherein said semiconductor wafer has a device region in which said plurality of devices are formed on the face side, and a peripheral marginal region surrounding said device region, and that region of said back-side surface of said semiconductor wafer which corresponds to said device region is preliminarily ground before etching so that an annular projected part is formed in that region of said back-side surface of said semiconductor wafer which corresponds to said peripheral marginal region.
